(19) United States
(12) Patent Application Publication
(10) Pub. No.: US 2026/0245606 A1
(43) Pub. Date: Aug. 20, 2026

(54) SEMICONDUCTOR STORAGE DEVICE

(71) Applicant: Kioxia Corporation, Tokyo (JP)

(72) Inventors: Takeshi AOKI, Ebina Kanagawa (JP); Shinji MIYANO, Yokohama Kanagawa (JP)

(73) Assignee: Kioxia Corporation, Tokyo (JP)

(21) Appl. No.: 19/320,244

(22) Filed: Sep. 5, 2025

(30) Foreign Application Priority Data
Feb. 14, 2025 (JP) 2025-022502

(51) Int. Cl. G11C 11/405; G11C 5/06; G11C 11/4094; G11C 11/4096; G11C 11/4091

(52) U.S. Cl. CPC G11C 11/405; G11C 5/063; G11C 11/4094; G11C 11/4096; G11C 11/4091

(57) ABSTRACT

A memory includes first data-lines and first control-lines for writing, and second data-lines and second control-lines for reading. A memory cell includes a first transistor having a gate connected to a first control-line and one end connected to a first data-line, a second transistor having a gate connected to a second control-line and one end connected to a second data-line, and a third transistor having a gate connected to another end of the first transistor and having one end connected to another end of the second transistor. A third and fourth data-lines respectively correspond to the first and second data-lines. A detector has an input part connected to the fourth data-line. A retention circuit is arranged between an output part of the detector and the third data-line. A fourth transistor is arranged between the output part of the detector and the third data-line.

### CROSS REFERENCE TO RELATED APPLICATIONS

This application is based upon and claims the benefit of priority from the prior Japanese Patent Application No. 2025-022502, filed on Feb. 14, 2025, the entire contents of which are incorporated herein by reference.

### FIELD

The embodiments of the present invention relate to a semiconductor storage device.

### BACKGROUND

A gain cell memory is developed as an alternative to a memory cell of a DRAM (Dynamic Random Access Memory). In a DRAM, a refresh operation of writing back stored data to the same memory cell cannot be performed during a read operation or a write operation.

### BRIEF DESCRIPTION OF THE DRAWINGS

FIG. 1 is a circuit diagram illustrating a configuration example of a single memory cell according to a first embodiment;

FIG. 2A is a perspective view illustrating a configuration example of a gain cell memory according to the first embodiment;

FIG. 2B is a perspective view illustrating another configuration example of the gain cell memory according to the first embodiment;

FIG. 3 is a diagram illustrating another configuration example of the gain cell memory according to the first embodiment;

FIG. 4 is a circuit diagram illustrating one example of an internal configuration of a latch circuit;

FIG. 5 is a timing chart illustrating an operation example of the gain cell memory according to the first embodiment;

FIG. 6 is a timing chart illustrating an operation example of a gain cell memory according to a second embodiment;

FIG. 7 is a diagram illustrating a configuration example of a gain cell memory according to a third embodiment; and

FIG. 8 is a circuit diagram illustrating a configuration example of a sense amplifier.

### DETAILED DESCRIPTION

In general, according to the embodiment, a semiconductor storage device comprises: a plurality of first data lines and a plurality of first control lines to be used for writing of data; and a plurality of second data lines and a plurality of second control lines to be used for reading of data.

A plurality of memory cells respectively comprises a first transistor having a gate connected to any of the first control lines and one end connected to any of the first data lines, a second transistor having a gate connected to any of the second control lines and one end connected to any of the second data lines, and a third transistor having a gate connected to another end of the first transistor to retain data from the first data line and having one end connected to another end of the second transistor to be brought to a conduction state according to the data. A third data line is arranged corresponding to the first data lines. A fourth data line is arranged corresponding to the second data lines.

A detection circuit is arranged corresponding to the third or fourth data line, has an input part connected to the fourth data line, and is configured to detect the data. A retention circuit corresponds to the third or fourth data line, is located between an output part of the detection circuit and the third data line, and is configured to retain the data detected by the detection circuit. A fourth transistor is arranged corresponding to the third or fourth data line and is located between the output part of the detection circuit and the third data line. Hereinafter, devices of the present disclosure will be described with reference to the drawings.

The present invention is not limited to the embodiments. In the present specification and the drawings, elements identical to those described in the foregoing drawings are denoted by like reference characters and detailed explanations thereof are omitted as appropriate.

### First embodiment

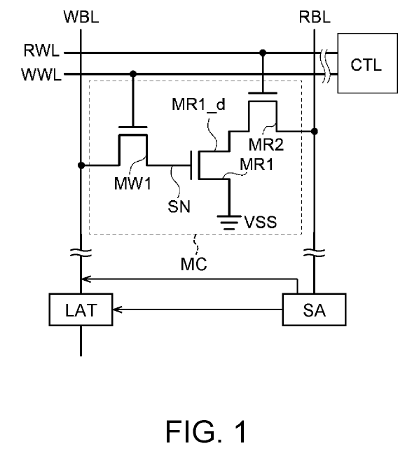

FIG. 1 is a circuit diagram illustrating a configuration example of a single memory cell according to a first embodiment. A memory cell MC of a gain cell memory is constituted of three transistors MW1, MR1, and MR2. Each of the transistors MW1, MR1, and MR2 is constituted of an n-type MOSFET (Metal Oxide Semiconductor Field Effect Transistor), for example.

The gate of the transistor MW1 as a first transistor is connected to a write word line WWL as a first control line. One electrode of the transistor MW1 is connected to a write bit line WBL as a first data line. The other electrode of the transistor MW1 is connected to the gate of the transistor MR1. One electrode and the other electrode of the transistor MW1 function as a source electrode or a drain electrode according to a voltage supplied to the transistor MW1. The transistor MW1 connects the write bit line WBL to the gate (hereinafter, also "sense node SN") of the transistor MR1, which functions as a sense node SN under control of the write word line WWL. The transistor MW1 transmits the voltage of the write bit line WBL to the sense node SN when in a conduction state (an on-state). The transistor MW1 holds the voltage of the sense node SN when in a non-conduction state (an off-state). In this way, the transistor MW1 can write a voltage (data) from the write bit line WBL to the sense node SN or can cause a written voltage (data) to be retained in the sense node SN.

The gate of the transistor MR1 as a third transistor is connected to the other electrode of the transistor MW1 and functions as a sense node SN. One electrode (for example, the source) of the transistor MR1 is connected to a low-voltage source VSS. The other electrode (for example, the drain) of the transistor MR1 is connected to one electrode of the transistor MR2. The transistor MR1 is brought to a conduction state according to a voltage (that is, data) of the sense node SN. For example, when the sense node SN is kept at a high-level voltage (for example, data "1"), the transistor MR1 is brought to an on-state. When the sense node SN is kept at a low-level voltage (for example, data "0"), the transistor MR1 is brought to an off-state.

The gate of the transistor MR2 as a second transistor is connected to a read word line RWL as a second control line. One electrode of the transistor MR2 is connected to the drain of the transistor MR1. The other electrode of the transistor MR2 is connected to a read bit line RBL as a second data line. One electrode and the other electrode of the transistor MR2 can function as a source electrode or a drain electrode according to a voltage supplied to the transistor MR2. The transistor MR2 connects the read bit line RWL to the drain of the transistor MR1 under control of the read word line RWL. The transistor MR1 is in a state (the on-state or the off-state) according to a voltage (data) retained in the sense node SN. When the transistor MR2 connects the read bit line RBL to the transistor MR1 at a time of the on-state, charges from the read bit line RBL flow to the low-voltage source VSS according to a state of the transistor MR1. When the transistor MR1 is in the on-state, the charges from the read bit line RBL flow to the low-voltage source VSS and the voltage of the read bit line RBL lowers. When the transistor MR1 is in the off-state, few charges flow from the read bit line RBL to the low-voltage source VSS and the voltage of the read bit line RBL is kept high. Accordingly, a voltage based on data retained in the sense node SN is transmitted to the read bit line RBL.

A sense amplifier SA as a detection circuit is connected to the read bit line RBL. The sense amplifier SA is not directly connected to the write bit line WBL. The sense amplifier SA detects read data on the basis of the voltage of the read bit line RBL. The read data latched by the sense simplifier SA is transmitted outside via a latch circuit LAT. The sense amplifier SA also performs precharging of the read bit line RBL. In a refresh operation, the sense amplifier SA directly writes back the read data to the write bit line WBL without the latch circuit LAT.

The latch circuit LAT is connected to the write bit line WBL and the sense amplifier SA. The latch circuit LAT latches data to be written from outside and applies a voltage corresponding to the data to be written to the write bit line WBL. The latch circuit LAT temporarily latches read data from the sense amplifier SA. The read data latched by the latch circuit LAT is transmitted outside at a predetermined timing.

A controller CTL is connected to the write word line WWL and the read word line RWL and controls voltages of the write word line WWL and the read word line RWL.

The write word line WWL and the write bit line WBL are lines to be used for writing of data. The read word line RWL and the read bit line RBL are lines to be used for reading of data. In this way, a gain cell memory uses word lines and bit lines differing between a data write operation and a data read operation. This enables a gain cell memory to read data while maintaining data in a sense node SN (non-destructive read). One memory cell MC is constituted of the three transistors MW1, MR1, and MR2 and does not have a capacitor that is difficult to downscale as that in a DRAM. Therefore, a gain cell memory is superior in downscaling.

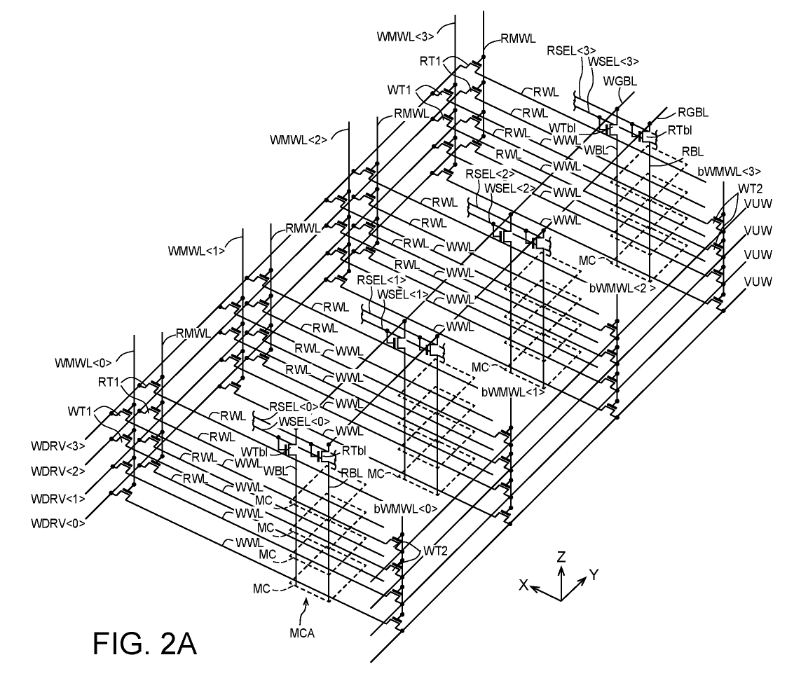

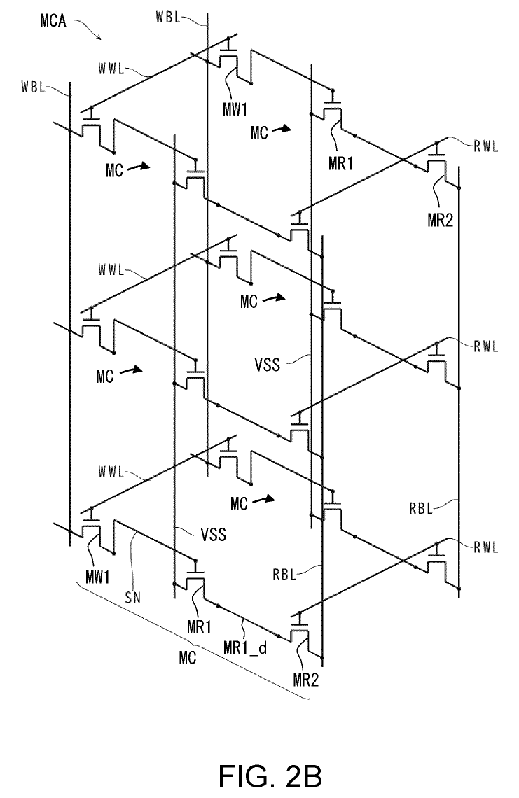

FIGS. 2A and 2B are perspective views illustrating a configuration example the gain cell memory according to the first embodiment. The gain cell memory according to the present embodiment includes a three-dimensional memory cell array where a plurality of the memory cells MC are arrayed three-dimensionally. The memory cells MC are arrayed in a matrix including a plurality of rows and a plurality of columns. A row is an array of the memory cells MC in an X direction. A column is an array of the memory cells MC in a Z direction. Furthermore, matrixes of the memory cells MC are arrayed in a Y direction. Accordingly, a memory cell array MCA is a three-dimensional array where the memory cells MC are arrayed three-dimensionally. The number of rows, the number of columns, and the number of matrixes of the memory cells MC are not particularly limited to the illustrated example. The memory cell array MCA is described below with reference to FIG. 2A.

A plurality of write word lines WWL are provided corresponding to a plurality of rows of memory cells MC, respectively. A plurality of read word lines RWL as a plurality of second control lines are also provided corresponding to the rows of the memory cells MC, respectively. The write word lines WWL are used for writing of data and extend in the X direction. The read word lines RWL are used for reading of data and extend in the X direction.

Each drive line WDRV is provided in common to a plurality of write word lines WWL and a plurality of read word lines RWL arrayed in the Y direction. The drive line WDRV transmits a selection voltage for performing writing of data. A plurality of the drive lines WDRV each extend in the Y direction and are arrayed in the Z direction.

A plurality of transistors WT1 are connected between a plurality of write word lines WWL and an associated drive line WDRV, respectively. One electrodes of the transistors WT1 are connected to the write word lines WWL, respectively. The other electrodes of a plurality of transistors WT1 arrayed in the Y direction are connected in common to one drive line WDRV. One electrode and the other electrode of each of the transistors WT1, and transistors RT1, WT2, WTb1, and RTb1 can function as a source electrode or a drain electrode according to a voltage supplied to the transistors WT1, RT1, WT2, WTb1, and RTb1.

A plurality of transistors RT1 are connected between a plurality of read word lines RWL and an associated drive line WDRV, respectively. One electrodes of the transistors RT1 are connected to the read word lines RWL, respectively. The other electrodes of a plurality of transistors RT1 arrayed in the Y direction are connected in common to one drive line WDRV. The transistors WT1 and RT1 arrayed in the Y direction are connected in common to one drive line WDRV.

Each write main word line WMWL is connected in common to the gates of a plurality of transistors WT1 arrayed in the Z direction. That is, each write main word line WMWL is provided in common to a plurality of write word lines WWL arrayed in the Z direction. A plurality of write main word lines WMWL each extend in the Z direction and are arrayed in the Y direction. Each of the write main word lines WMWL selectively brings the transistors WT1 connected thereto to the on-state and connects the drive lines WDRV to the corresponding write word lines WWL, respectively. The write main word lines WMWL arrayed in the Y direction are driven independently of each other. Therefore, the transistors WT1 illustrated in FIG. 2A are controlled to the on-state or the off-state with respect to each plurality of rows arrayed in the Z direction.

Each read main word line RMWL is connected in common to the gates of a plurality of transistors RT1 arrayed in the Z direction. That is, each read main word line RMWL is provided in common to a plurality of read word lines RWL arrayed in the Z direction. A plurality of read main word lines RMWL each extend in the Z direction and are arrayed in the Y direction. The read main word lines RMWL bring a plurality of transistors RT1 connected thereto to the on-state to connect the drive lines WDRV to the corresponding read word lines RWL. A plurality of read main word lines RMWL arrayed in the Y direction are individually driven. Therefore, the transistors RT1 illustrated in FIG. 2A are controlled to the on-state or the off-state with respect to each plurality of rows arrayed in the Z direction.

Each write-pass voltage line VUW is provided in common to a plurality of write word lines WWL arrayed in the Y direction. The write-pass voltage line VUW transmits a non-selection voltage for not performing writing of data. A plurality of write-pass voltage lines VUW each extend in the Y direction and are arrayed in the Z direction.

A plurality of transistors WT2 are connected between a plurality of write word lines WWL and an associated write-pass voltage line VUW, respectively. One electrodes of the transistors WT2 are connected to the write word lines WWL, respectively. The other electrodes of a plurality of transistors WT2 arrayed in the Y direction are connected in common to one write-pass voltage line VUW. Meanwhile, the read word lines RWL are electrically separated from the write-pass voltage lines VUW. When the non-selection voltage is fixed, the write-pass voltage lines VUW may be short-circuited with each other as one drive line.

Each non-selection main word line bWMWL is connected in common to a plurality of transistors WT2 arrayed in the Z direction. A plurality of non-selection main word lines bWMWL each extend in the Z direction and are arrayed in the Y direction. The non-selection main word lines bWMWL bring transistors WT2 connected to write word lines WWL corresponding to memory cells MC to which data is not to be written to the on-state to connect the associated write-pass voltage lines VUW to the write word lines WWL, respectively.

A plurality of write bit lines WBL are provided corresponding to a plurality of columns of memory cells MC, respectively. A plurality of read bit lines RBL as a plurality of second data lines are also provided corresponding to the columns of the memory cells MC, respectively. In FIG. 2A, only one array of write bit lines WBL and one array of read bit lines RBL arrayed in the Y direction are illustrated. The write bit lines WBL are used for writing of data and extend in the Z direction. The read bit lines RBL are used for reading of data and extend in the Z direction. The read bit lines RBL, the write bit lines WBL, the write main word lines WMWL, the read main word lines RMWL, and the non-selection main word lines bWMWL extend in the Z direction.

Each write global bit line WGBL is provided in common to a plurality of write bit lines WBL arrayed in the Y direction. A plurality of write global bit lines WGBL each extend in the Y direction and are arrayed in the X direction. In FIG. 2A, only one write global bit line WGBL is illustrated. Each of the write global bit lines WGBL is connected to a write bit line WBL selected from the corresponding write bit lines WBL to transmit data from the latch circuit LAT or the sense amplifier SA to the selected write bit line WBL.

Each read global bit line RGBL is provided in common to a plurality of read bit lines RBL arrayed in the Y direction. A plurality of read global bit lines RGBL each extend in the Y direction and are arrayed in the X direction. In FIG. 2A, only one read global bit line RGBL is illustrated. Each of the read global bit lines RGBL is connected to a read bit line RBL selected from the corresponding read bit lines RBL to transmit data from the selected read bit line RBL to the sense amplifier SA.

Data of as many bits as pairs of the write global bit line WGBL and the read global bit line RGBL can be written or read at the same time. Data that can be written or read at the same time is referred to as "page".

With the layered bit line structure of the global bit lines WGBL and RGBL and the bit lines WBL and RBL, the capacity of each of the bit lines WBL and RBL can be decreased.

A plurality of transistors WTb1 are connected between a plurality of write bit lines WBL and an associated write global bit line WGBL, respectively. One electrodes of the transistors WTb1 are connected to the write bit lines WBL, respectively. The other electrodes of a plurality of transistors WTb1 arrayed in the Y direction are connected in common to one write global bit line WGBL. The gates of a plurality of transistors WTb1 arrayed in the X direction are connected in common to an associated write selection line WSEL. A plurality of write selection lines WSEL each extend in the X direction and are arrayed in the Y direction. Each transistor WTb1 connects one of the write bit lines WBL to one write global bit line WGBL.

In a write operation, one of the write selection lines WSEL is selectively driven. A plurality of transistors WTb1 connected to the selected write selection line WSEL are brought to the on-state and each electrically connect between the corresponding write bit line WBL and the corresponding write global bit line WGBL. Accordingly, the transistors WTb1 connected to the selected write selection line WSEL each transmit data from the latch circuit LAT or the sense amplifier SA, from the corresponding write global bit lines WGBL to the corresponding write bit lines WBL, respectively.

It is preferable that the transistors WTb1 are provided to decrease the capacity of each of the write bit lines WBL to enable a high-speed operation of the write bit lines WBL. However, when the operation speed is not considered, it is possible that the transistors WTb1 are not provided.

A plurality of transistors RTb1 are connected between a plurality of read bit lines RBL and an associated read global bit line RGBL, respectively. One electrodes of the transistors RTb1 are connected to the read bit lines RBL, respectively. The other electrodes of a plurality of transistors RTb1 arrayed in the Y direction are connected in common to one read global bit line RGBL. The gates of a plurality of transistors RTb1 arrayed in the X direction are connected in common to an associated read selection line RSEL. A plurality of read selection lines RSEL each extend in the X direction and are arrayed in the Y direction. Each of the transistors RTb1 connects one of the read bit lines RBL to one read global bit line RGBL.

In a read operation, one of the read selection lines RSEL is selectively driven. A plurality of transistors RTb1 connected to the selected read selection line RSEL are brought to the on-state and each electrically connect between the corresponding read bit line RBL and the corresponding the read global bit line RGBL. Accordingly, the transistors RTb1 connected to the selected read selection line RSEL each transmit data from the associated memory cells MC, from the corresponding read bit lines RBL to the corresponding read global bit lines RGBL, respectively.

A plurality of memory cells MC are provided corresponding to intersecting portions between a pair of a write word line WWL and a read word line RWL adjacent to each other in the Y direction and a pair of a write bit line WBL and a read bit line RBL adjacent to each other in the X direction, respectively. Therefore, the memory according to the present embodiment can write data to one memory cell MC by selecting one write word line WWL and one write bit line WBL at the time of writing. At the time of reading, the memory can read data from one memory cell MC by selecting one read word line RWL and one read bit line RBL.

A layer including a plurality of write word lines WWL, a plurality of read word lines RWL, and a plurality of memory cells MC corresponding to one drive line WDRV is assumed as a set. In this case, one write main word line WMWL is connected in common to the gates of a plurality of transistors WT1 corresponding to a plurality of sets. One read main word line RMWL is connected in common to the gates of a plurality of transistors RT1 corresponding to a plurality of sets. Further, one non-selection main word line bWMWL is connected in common to the gates of a plurality of transistors WT2 corresponding to a plurality of sets. One write main word line WMWL is provided in common to a plurality of write word lines WWL corresponding to a plurality of sets. One read main word line RMWL is provided in common to a plurality of read word lines RWL corresponding to a plurality of sets.

One end of each of the write word lines WWL is connected to a drive line WDRV via a transistor WT1, and the other end thereof is connected to a write-pass voltage line VUW via a transistor WT2. Meanwhile, one end of each of the read word lines RWL is connected to a drive line WDRV via a transistor RT1 and the other end thereof is not connected to a transistor, a drive line, or the like.

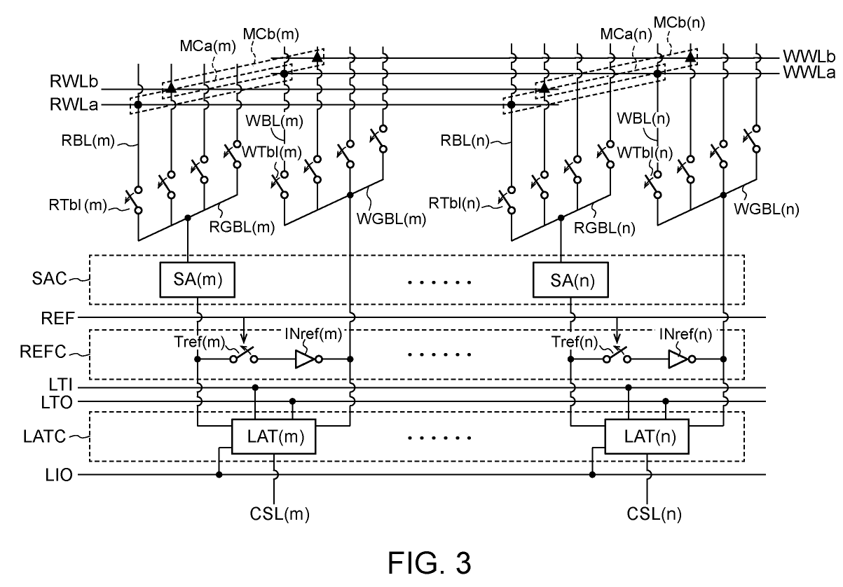

FIG. 3 is a diagram illustrating a configuration example of a gain cell memory according to the first embodiment. In FIG. 3, the arrangement relation between the memory cells MC and the global bit lines RGBL and WGBL is opposite in the Z direction to the arrangement relation illustrated in FIG. 2A. However, the configuration illustrated FIG. 3 may be the same as that in FIG. 2A.

A memory cell MCa(m) is provided corresponding to an intersection between a read word line RWLa and a read bit line RBL(m) and an intersection between a write word line WWLa and a write bit line WBL(m). A memory cell MCa(n) is provided corresponding to an intersection between the read word line RWLa and a read bit line RBL(n) and an intersection between the write word line WWLa and a write bit line WBL(n). Each of the memory cells MCa(m) and MCa(n) is represented by a broken frame including "black dots" in FIG. 3.

A memory cell MCb(m) is provided corresponding to an intersection between a read word line RWLb and a read bit line RBL(m) and an intersection between a write word line WWLb and a write bit line WBL(m). A memory cell MCb(n) is provided corresponding to an intersection between the read word line RWLb and a read bit line RBL(n) and an intersection between the write word line WWLb and a write bit line WBL(n). Each of the memory cells MCb(m) and MCb(n) is represented by a broken frame including "black triangles" in FIG. 3. Any integers can be used as m and n. While a configuration corresponding to two columns of m and n is illustrated in FIG. 3, a configuration corresponding to three or more columns may be provided.

A column is a unit configuration that can be selected with a column selection signal CSL in a read operation and a write operation. One-bit data can be read from or written to each column at one time. Data of a plurality of columns that can be simultaneously read or written is "page".

A plurality of read bit lines RBL(m) are connected to a sense amplifier SA(m) via a plurality of transistors RTbl(m), respectively.

A plurality of read bit lines RBL(n) are connected to a sense amplifier SA(n) via a plurality of transistors RTbl(n), respectively.

A detector SAC includes a plurality of sense amplifiers SA(m), SA(n). The number of sense amplifiers included in the detector SAC is not limited to a specific value. In the following explanations, a configuration denoted by a reference sign with (m) is described and descriptions of a configuration with (n) are omitted in some cases. In a case where the columns m and n are not distinguished from each other, notations (m) and (n) are sometimes omitted.

In this example, m is a column ID of a plurality of memory cell groups sharing global bit lines WGBL(m) and RGBL(m), and n is a column ID of a plurality of memory cell groups sharing global bit lines WGBL(n) and RGBL(n).

A sense amplifier SA is provided for each global bit line RGBL. That is, a sense amplifier SA is provided for each column. For example, the sense amplifier SA(m) is connected to the read global bit line RGBL(m) corresponding thereto and is not connected to the write global bit line WGBL(m). An input part of the sense amplifier SA(m) is connected to the corresponding read global bit line RGBL(m). An output part of the sense amplifier SA(m) is connected to a latch circuit LAT(m) and a transistor Tref(m).

A refresher REFC includes a plurality of transistors Tref(m), Tref(n) and a plurality of inverters INref(m), INref(n).

A transistor Tref and an inverter INref are both provided corresponding to a write global bit line WGBL or a sense amplifier SA. That is, a pair of a transistor Tref and an inverter INref is also provided corresponding to each column. For example, the transistor Tref(m) and the inverter INref(m) are connected in series between the output part of the sense amplifier SA(m) and the write global bit line WGBL(m) corresponding thereto. The transistor Tref(m) is provided corresponding to and in parallel to the latch circuit LAT(m) between the output part of the sense amplifier S(m) and the write global bit line WGBL(m) corresponding thereto. The inverter INref(m) is connected between the transistor Tref(m) and the write global bit line WGBL(m) corresponding thereto. The transistor Tref(m) can be constituted of an n-type MOSFET, for example. The inverter INref(m) can be constituted of a CMOS (Complementary MOS), for example.

One end (for example, a drain) of the transistor Tref(m) is connected to the output part of the sense amplifier SA(m). In the present embodiment, one end of the transistor Tref(m) is connected to an output part for a non-inverted signal of the sense amplifier SA(m). The other end (for example, a source) of the transistor Tref(m) is connected to an input part of the inverter INref(m). A gate of the transistor Tref(m) is connected to a signal line that transmits a refresh signal REF. The refresh signal REF is a signal activated during a refresh operation period.

The input part of the inverter INref(m) is connected to the other end of the transistor Tref(m). An output part of the inverter INref(m) is connected to the write global bit line WGBL(m).

Accordingly, the transistor Tref(m) and the inverter Inref(m) can directly write back read data detected by the sense amplifier SA(m) to the write global bit line WGBL(m) without the latch circuit LAT(m) and the sense amplifier SA(m). That is, in the refresh operation, the transistor Tref(m) and the inverter INref(m) function as a bypass route.

In the present embodiment, the transistor Tref(m) receives a non-inverted signal of read data from the sense amplifier SA(m). The inverter INref(m) inverts this read data and outputs an inverted signal. Accordingly, the inverted signal of the read data is transmitted to the write global bit line WGBL(m) and data of an inverted logic is transmitted to a sense node SN of the memory cell MC in FIG. 1. The memory cell MC in FIG. 1 outputs data of a voltage level of the opposite logic to the voltage level of the sense node SN. Therefore, with writing back of data of the opposite logic to that of the read data to the sense node SN, the writing back of the read data is normally completed.

The transistor Tref(n) and the inverter INref(n) have substantially the same configuration with respect to the sense amplifier SA(n) and the write global bit line WGBL(n) and similarly function as a bypass route.

A latch part LATC includes a plurality of latch circuits LAT(m), LAT(n). A latch circuit LAT is provided corresponding to a write global bit line WGBL or a sense amplifier SA. That is, a latch circuit LAT is also provided corresponding to each column. For example, the latch circuit LAT(m) is connected between the output part of the sense amplifier SA(m) and the write global bit line WGBL(m) corresponding thereto. In the present embodiment, the latch circuit LAT(m) is connected to the output part for a non-inverted signal of the sense amplifier SA(m) and receives a non-inverted signal of read data.

The latch circuit LAT(m) operates in accordance with control signals LTI and LTO and a column selection signal CSL(m). The control signal LTI is a signal for inputting read data from the sense amplifier SA(m) to the latch circuit LAT(m). The control signal LTO is a signal for outputting data to be written, which has been loaded from outside, from the latch circuit LAT(m) into the write global bit line WGBL(m). The column selection signal CSL(m) is a signal for outputting latched read data to an input/output signal line LIO or a signal for loading data to be written into the latch circuit LAT(m). A signal line for the refresh signal REF, signal lines for the control signals LTI and LTO, and the input/output signal line LIO are provided in common to columns in the detector SAC, the refresher REFC, and the latch part LATC.

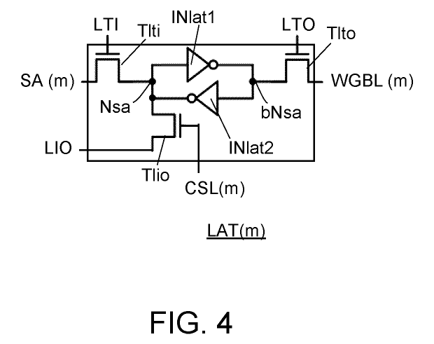

FIG. 4 is a circuit diagram illustrating one example of an internal configuration of a latch circuit. Since the internal configuration of the latch circuit LAT(n) is the same as that of the latch circuit LAT(m), descriptions thereof are omitted.

The latch circuit LAT(m) includes transistors Tlti, Tlto, and Tlio, and inverters INlat1 and INlat2.

One end (for example, a drain) of the transistor Tlti is connected to the output part of the sense amplifier SA(m). The other end (for example, a source) of the transistor Tlti is connected to an input part (a node Nsa) of the inverter INlat1 and an output part of the inverter INlat2. A gate of the transistor Tlti is connected to the signal line for the control signal LTI.

One end (for example, a drain) of the transistor Tlto is connected to an output part (a node bNsa) of the inverter INlat1 and an input part of the inverter INlat2. The other end (for example, a source) of the transistor Tlto is connected to the write global bit line WGBL(m). A gate of the transistor Tlto is connected to the signal line for the control signal LTO.

One end (for example, a drain) of the transistor Tlio is connected to the input part (the node Nsa) of the inverter INlat1 and the output part of the inverter INlat2. The other end (for example, a source) of the transistor Tlio is connected to the input/output signal line LIO. A gate of the transistor Tlio is connected to the signal line for the column selection signal CSL(m), which selectively connects one of the latch circuits LAT to the input/output signal line LIO.

Each of the transistors Tlti, Tlto, and Tlio can be constituted of an n-type MOSFET, for example.

The inverters INlat1 and INlat2 constitute a latch circuit by connecting the input part of one thereof to the output part of the other thereof. For example, the input part of the inverter INlat1 and the output part of the inverter INlat2 are connected at the node Nsa. The output part of the inverter INlat1 and the input part of the inverter INlat2 are connected at the node bNsa. Each of the inverters INlat1 and INlat2 can be constituted of a CMOS.

The node Nsa retains the non-inverted signal of data from the sense amplifier SA(m). The node bNsa retains the opposite logic to data at the node Nsa (an inverted signal of data from the sense amplifier SA(m)).

In a read operation, when the control signal LTI is activated to a high-level voltage, the transistor Tlti is brought to a conduction state (ON) and read data from the sense amplifier SA(m) is retained by the inverters INlat1 and INlat2.

When the column selection signal CSL(m) is activated to a high-level voltage, the transistor Tlio is turned on and the read data retained by the cross-coupled inverters INlat1 and INlat2 is transmitted to the input/output signal line LIO. The read data can be thereby output to outside.

When the control signal LTO is activated to a high-level voltage, the transistor Tlto is turned on and the read data retained by the inverters INlat1 and INlat2 is transmitted to the write global bit line WGBL(m). The read data can be thereby written back to the memory cell MCa(m) or MCb(m).

The control signal LTI is activated to a high-level voltage and the read data from the sense amplifier SA is retained by the inverters INlat1 and INlat2. In a write operation, the column selection signal CSL(m) is subsequently activated to a high-level voltage, data to be written from the input/output signal line LIO is transmitted to the inverters INlat1 and INlat2, and the data retained by the inverters INlat1 and INlat2 is updated with the data to be written.

The control signal LTO is subsequently activated to a high-level voltage, and the data to be written, which has been retained by the inverters INlat1 and INlat2, is transmitted to the write global bit line WGBL(m). The data to be written can be thereby written to the memory cell MCa(m) or MCb(m).

Data transmitted from the latch circuit LAT(m) to the write global bit line WGBL(m) is inverted data of the opposite logic to read data from the sense amplifier SA(m) or data to be written from the input/output signal line LIO. This is because read data transmitted from the memory cell MCa(m) or MCb(m) in FIG. 1 to the read bit line RBL(m) has the opposite logic to that of data stored at the sense node SN(m).

In a refresh operation, when the refresh signal REF is activated to a high-level voltage, the transistor Tref(m) is turned on. Accordingly, read data from the sense amplifier SA(m) is inverted through the inverter INref(m) and is transmitted to the write global bit line WGBL(m). At this time, the refresher REFC transmits (bypasses) the read data to the write global bit line WGBL(m) without the latch circuit LAT(m) and the sense amplifier SA(m). The memory cell MCa(m) or MCb(m) can be thereby refreshed. The refresh operation is an operation of temporarily reading data stored in the memory cell MCa(m) or MCb(m) and writing the data back to the same memory cell.

As described above, read data transmitted from a memory cell MC to a read bit line RBL has the opposite logic to that of data stored at the sense node SN. Therefore, the read data is transmitted to a write global bit line WGBL after the logic is inverted by the inverter INref. This enables the refresh operation to be normally completed.

Operations of the sense amplifier SA(n), the transistor Tref(n), the latch circuit LAT(n), and the like can be substantially the same as those of the sense amplifier SA(m), the transistor Tref(m), the latch circuit LAT(m), and the like.

An array chip including the memory cells MCa(m), MCa(n), MCb(m), and MCb(n) can be configured as a semiconductor chip different from a peripheral circuit chip including the detector SAC, the refresher REFC, and the latch part LATC and can be stacked on the peripheral circuit chip. This can reduce the chip area.

Operations of the gain cell memory according to the present embodiment is described in more detail next.

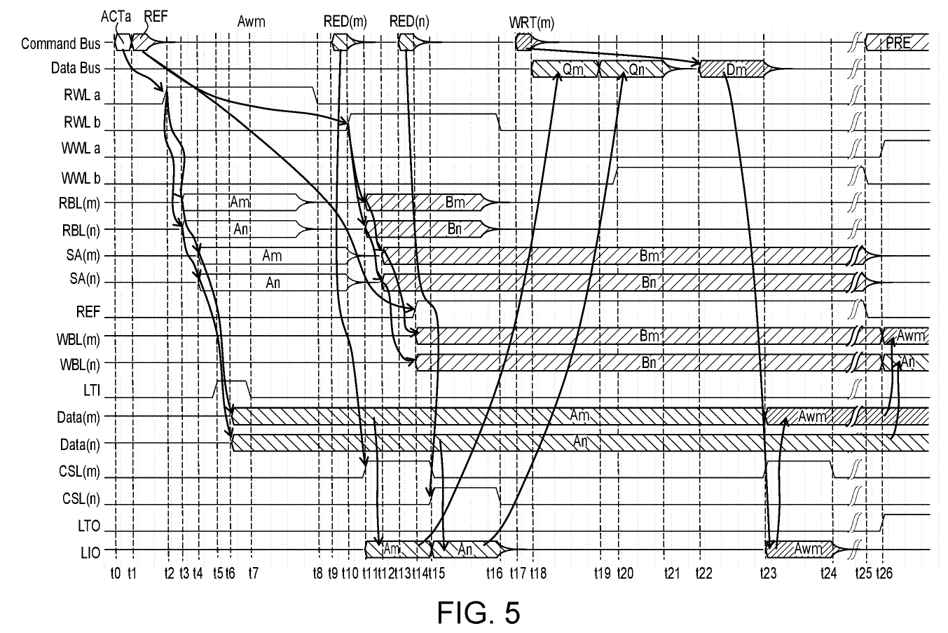

FIG. 5 is a timing chart illustrating an operation example of the gain cell memory according to the first embodiment. In this operation example, data is read from the memory cells MCa(m) and MCa(n) in FIG. 3 and data is written to the memory cell MCa(m). In parallel thereto, a refresh operation is performed to the memory cells MCb(m) and MCb(n).

First, an active command ACTa is issued at t0 and a refresh command REF is subsequently issued at t1. The active command ACTa is a command for accessing the memory cells MCa(m) and MCa(n) with an index "a", for example. The refresh command REF is a command for performing a refresh operation. In this example, the refresh operation is performed to the memory cells MCb(m) and MCb(n) with an index "b" for the sake of convenience. An address b of the refresh targets is determined by a counter in the memory.

With the issuance of the active command ACTa, the read word line RWLa is activated to a high-level voltage at t2. Accordingly, at t3, data Am in the memory cell MCa(m) is transmitted to the read bit line RBL(m). Data An in the memory cell MCa(n) is transmitted to the read bit line RBL(n). At this time, the reading transistors RTbl(m) and RTbl(n) corresponding to the memory cells MCa(m) and MCa(n) in FIG. 3 are in the on-state.

Next, at t4, the sense amplifier SA(m) detects the data Am and amplifies the data Am. The sense amplifier SA(n) detects the data An and amplifies the data An.

Next, when the control signal LTI is activated to a high-level voltage at t5, the transistors Tlti (see FIG. 4) in the latch circuits LAT(m) and LAT(n) are turned on. Accordingly, the latch circuits LAT(m) and LAT(n) load the data Am and An and latch the data, respectively, at t6. When the control signal LTI is deactivated to a low-level voltage at t7, the transistors Tlti in the latch circuits LAT(m) and LAT(n) are turned off. Accordingly, the latch circuits LAT(m) and LAT(n) are electrically separated from the sense amplifiers SA(m) and SA(n), respectively. At this time, the transistors Tlio and Tlto are also kept in an off-state. Therefore, the latch circuits LAT(m) and LAT(n) retain the data Am and An at the nodes Nsa, respectively. The latch circuits LAT(m) and LAT(n) retain inverted signals of the data Am and An at the nodes bNsa, respectively.

When the read word line RWLa is deactivated to a low-level voltage at t8, the memory cells MCa(m) and Mca(n) are electrically separated from the read bit lines RBL(m) and RBL(n), respectively. At this time, the latch circuits LAT(m) and LAT(n) have been electrically separated from the sense amplifiers SA(m) and SA(n) in a state retaining the data Am and An, respectively. Therefore, the sense amplifiers SA(m) and SA(n) can operate independently of the latch circuits LAT(m) and LAT(n). Accordingly, a read operation of the latch circuits LAT(m) and LAT(n) and a refresh operation of the sense amplifiers SA(m) and SA(n) can be thereafter performed simultaneously and parallelly.

### Read operation of data Am and An from latch circuits LAT(m) and LAT(n)

At t9, a read command RED(m) is issued. Accordingly, at t11, the column selection signal CSL(m) is activated to a high-level voltage and the transistor Tlio in the latch circuit LAT(m) in FIG. 4 is turned on. When the transistor Tlio is turned on, the data Am latched by the latch circuit LAT(m) is output to the input/output signal line LIO. Accordingly, the data Am is transmitted to the input/output signal line LIO at t11 to t15 and is read to outside as data Qm at t18 to t19.

At t13, a read command RED(n) is issued. Accordingly, at t14, the column selection signal CSL(m) is deactivated to a low-level voltage and the column selection signal CSL(n) is activated to a high-level voltage. Therefore, the transistor Tlio in the latch circuit LAT(m) in FIG. 4 is turned off and the transistor Tlio in the latch circuit LAT(n) is turned on. When the transistor Tlio is turned on, the data An latched by the latch circuit LAT(n) is output to the input/output signal line LIO. Accordingly, the data An is transmitted to the input/output signal line LIO at t15 to t16. When the column selection line CSL(n) is deactivated to a low-level voltage at t16, output of the data An from the latch circuit LAT(n) to the input/output signal line LIO ends. The data An is read to outside as data Qn at t19 to t21.

### Refresh operation for memory cells MCb(m) and MCb(n)

Meanwhile, with the issuance of the refresh command REF, the read word line RWLb is activated to a high-level voltage at t10 after the read word line RWLa is deactivated at t8. Accordingly, at t11, data Bm in the memory cell MCb(m) is transmitted to the read bit line RBL(m). Data Bn in the memory cell MCb(n) is transmitted to the read bit line RBL(n). The reading transistors RTbl(m) and RTbl(n) corresponding to the memory cells MCb(m) and MCb(n) in FIG. 3 are in the on-state. Since the read word line RWLa has already been deactivated at this time, the memory cells MCa(m) and MCa(n) have been electrically separated from the read global bit lines RGBL(m) and RGBL(n). Therefore, no problem occurs when the data Bm and Bn in the memory cells MCb(m) and MCb(n) is transmitted to the read global bit lines RGBL(m) and RGBL(n).

Next, at t12, the sense amplifier SA(m) detects the data Bm and amplifies the data Bm. The sense amplifier SA(n) detects the data Bn and amplifies the data Bn.

Next, when the refresh signal REF is activated to a high-level voltage at t14, the transistors Tref(m) and Tref(n) (see FIG. 4) are turned on. Accordingly, the data Bm detected by the sense amplifier SA(m) is transmitted to the write bit line WBL(m) via the transistor Tref(m) and the inverter Inref(m). That is, the data Bm detected by the sense amplifier SA(m) bypasses the latch circuit LAT(m) to be transmitted from the sense amplifier SA(m) to the write bit line WBL(m). The data Bn detected by the sense amplifier SA(n) is transmitted to the write bit line WBL(n) via the transistor Tref(n) and the inverter Inref(n). That is, the data Bn detected by the sense amplifier SA(n) bypasses the latch circuit LAT(n) to be transmitted from the sense amplifier SA(n) to the write bit line WBL(n). At this time, the writing transistors WTbl(m) and WTbl(n) corresponding to the memory cells MCb(m) and MCb(n) in FIG. 3 are in the on-state.

When the write word line WWLb is activated to a high-level voltage at t20, the transistors MW1 (see FIG. 1) of the memory cells MCb(m) and MCb(n) (see FIG. 3) are turned on. Accordingly, the data Bm is written back to the sense node SN of the memory cell MCb(m). The data Bn is written back to the sense node SN of the memory cell MCb(n). The writing back (the refresh operation) to the memory cells MCb(m) and MCb(n) is performed until the refresh signal REF and the write word line WWLb are deactivated to a low-level voltage at t25 (immediately before precharging is started).

The refresh operation for the memory cells MCb(m) and MCb(n) can be performed after the data Am and An in the memory cells MCa(m) and MCa(n) as reading targets is latched by the latch circuits LAT(m) and LAT(n) and the control signal LTI and the read word line RWLa are deactivated. Even when the latch circuits LAT(m) and LAT(n) are in the middle of outputting the data Am and An to outside (for example, at t11 to t21), the refresh operation can be performed to the memory cells MCb(m) and MCb(n) (for example, at t14 to t25). That is, the present embodiment enables a read operation and a refresh operation to be performed at overlapping timings.

### Write operation to memory cell MCa(m)

In the present embodiment, a write command WRT(m) for the memory cell MCa(m) is further issued at t17. With the issuance of the write command, data Dm is loaded at t22 to t23.

At t23 to t24, the data Dm is transmitted as data Awm to the input/output signal line LIO. When the column selection signal CSL(m) is activated to a high-level voltage, the data Awm is latched by the latch circuit LAT(m). Accordingly, the read data Am retained by the latch circuit LAT(m) is updated with the write data Awm at t23.

When the column selection signal CSL(m) is deactivated to a low-level voltage at t24, the latch circuit LAT(m) retains the write data Awm.

The refresh operation ends at t25. Next, when a precharge command PRE for performing writing back to the sense nodes SN of the memory cells MCa(m) and MCa(n) and precharging the write bit lines WBL(m) and WBL(n) is issued, the control signal LTO and the write word line WWLa are activated to a high-level voltage at t26. Accordingly, the transistors Tlto (see FIG. 4) of the latch circuits LAT(m) and LAT(n) are turned on.

At t26, the latch circuit LAT(m) transmits an inverted signal of the write data Awm to the write bit line WBL(m). Accordingly, the inverted signal of the write data Awm is retained at the sense node SN of the memory cell MCa(m). At this time, the writing transistor WTbl(m) corresponding to the memory cell MCa(m) in FIG. 3 is in the on-state. In this case, data read from the memory cell MCa(m) is a non-inverted signal of the data Awm.

Since the latch circuit LAT(n) is retaining the read data An as it is at t26, an inverted signal of the data An is transmitted to the write bit line WBL(n). Accordingly, the inverted signal of the data An is written back to the sense node SN of the memory cell MCa(n). At this time, the writing transistor WTbl(n) corresponding to the memory cell MCa(n) in FIG. 3 is in the on-state. In this case, data read from the memory cell MCa(n) is a non-inverted signal of the data An.

The refresh operation can be performed at a time overlapping a period (for example, t23 to t26) until the write data Awm is latched by the latch circuit LAT(m) and the control signal LTO is activated in a write operation. However, it is necessary that the refresh operation has been ended when the control signal LTO is activated (t26) in a precharge operation.

As described above, in the gain cell memory according to the present embodiment, while connected to a read global bit line RGBL, each of the sense amplifiers SA is not directly connected to a write global bit line WGBL. Therefore, while detecting data of memory cells MC, each of the sense amplifiers SA is not used for writing and writing back of data.

Meanwhile, each of the transistors Tref in the refresher REFC is provided between the output part of a sense amplifier SA and a write global bit line WGBL. Accordingly, in a refresh operation, data detected by a sense amplifier SA can be transmitted through a bypass to a write global bit line WGBL via a transistor Tref and can be written back to the original memory cell MC. That is, each of the transistors Tref can function as a bypass route in a refresh operation.

Each of the latch circuits LAT is connected in parallel to a transistor Tref between the output part of a sense amplifier SA and a write global bit line WGBL. Each of the latch circuits LAT can temporarily retain data detected by the corresponding sense amplifier SA. Data retained by a latch circuit LAT can be output to outside via the input/output signal line LIO and data to be written can be loaded from outside via the input/output signal line LIO. Data to be written, which has been loaded into the latch circuit LAT, can be written to a memory cell MC via the corresponding write global bit line WGBL. A read operation and a write operation can be accordingly performed.

With this configuration, in the gain cell memory, a sense amplifier SA and a transistor Tref can perform a detection operation and a refresh operation in a retention period in which a latch circuit LAT is retaining data. This is because the sense amplifier SA and the transistor Tref are electrically separated from the latch circuit LAT in the retention period and accordingly can operate independently of the latch circuit LAT without affecting the retained data in the latch circuit LAT. At this time, the latch circuit LAT can read data to outside in accordance with a read command or can load data to be written from outside to update the retained data in accordance with a write command, without being affected by the refresh operation.

In this way, in parallel to the operation of a latch circuit LAT, the corresponding sense amplifier SA can detect data of a memory cell MC and the corresponding transistor Tref can write back the detected data to the same memory cell MC. That is, a sense amplifier SA and the corresponding transistor Tref can perform a refresh operation in parallel to the operation of the corresponding latch circuit LAT.

For example, in a retention period after latch circuits LAT retain read data (t7) and before data (read data or data to be written) retained by the latch circuits LAT is written back or written to memory cells MC (t26) in FIG. 5, the sense amplifiers SA and the transistors Tref can perform the refresh operation (t14 to t25). That is, in the retention period, the sense amplifiers SA can detect data of memory cells MC as targets for the refresh operation. In the retention period, the transistors Tref are turned on by activation of the refresh signal REF and can write back data detected by the sense amplifiers SA from the sense amplifiers SA to memory cells MC as targets for the refresh operation without the latch circuits LAT. Since the latch circuits LAT are electrically separated from the corresponding read global bit lines RGBL and the corresponding write global bit lines WGBL in the retention period, no problem occurs even when the sense amplifiers SA and the transistors Tref independently perform the refresh operation.

Conversely, in a period in which latch circuits LAT are connected to the corresponding read global bit lines RGBL (a period from t5 to t7 in which the control signal LTI is activated), and a period in which latch circuits LAT are connected to the corresponding write global bit lines WGBL (in a period from t26 in which the control signal LTO is activated), the corresponding transistors Tref are in the off-state. That is, each of the transistors Tref is in the off-state when either the transistor Tlti or Tlto of the corresponding latch circuit LAT is on-state. Accordingly, collision of data Bm and Bn by a refresh operation with other read data Am and An or data Awn to be written on the read global bit line RGBL and the write global bit line WGBL can be suppressed.

A refresh operation may be performed to memory cells MC as reading targets or writing targets. While data retained by the corresponding latch circuits LAT is written back or written to the refreshed memory cells MC after the refresh operation in this case, no problem occurs.

In the gain cell memory according to the present embodiment, the detector SAC and the refresher REFC can perform a refresh operation at an overlapping timing during a read operation or a write operation of a latch circuit LAT. Therefore, a period in which a read operation and a write operation can be performed is less restricted by a refresh operation and an effective band width can be improved.

### Second embodiment

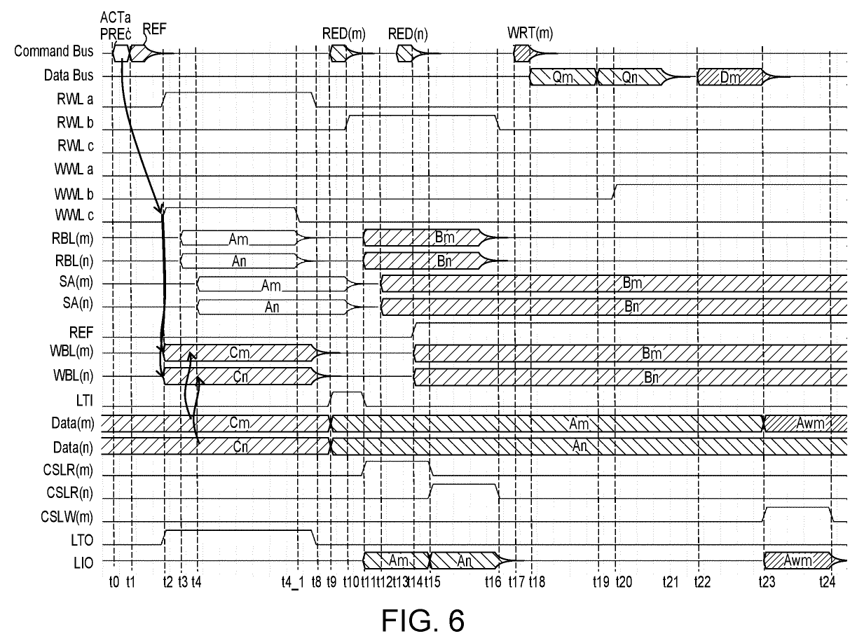

FIG. 6 is a timing chart illustrating an operation example of a gain cell memory according to a second embodiment. The configuration of the second embodiment can be identical to that of the first embodiment. In the second embodiment, in a period in which a sense amplifier SA detects data of a memory cell MCa, the corresponding latch circuit LAT writes back or writes data to a memory cell MCc.

In the first embodiment, when a sense amplifier SA detects data in a read operation, a read global bit line RGBL is used and a write global bit line WGBL is not used.

In the second embodiment, when sense amplifiers SA detect data of memory cells MCa in a read operation, latch circuits LAT write data to memory cells MCc via the corresponding write global bit lines WGBL. Although not illustrated in FIG. 6, a memory cell MCc is a different memory cell from a memory cell MCa while corresponding to the same global bit lines RGBL and WGBL as those for the memory cell MCa and belonging to the same column. A memory cell MCc is provided with respect to each pair of the global bit lines RGBL and WGBL (that is, with respect to each of the columns m, n) similarly to the memory cells MCa and MCb. A memory cell MCc(m) belongs to the column m and a memory cell MCc(n) belongs to the column n.

For example, first, at t0, an active command ACTa is issued and a precharge command PREc is issued. At t1, a refresh command REF is issued. Operations of the gain cell memory in accordance with the active command ACTa and the refresh command REF are the same as those in the first embodiment.

It is assumed that data to be written back or written to memory cells MCc is already retained by the latch circuits LAT(m) and LAT(n) at t0 by an operation before t0. For the sake of convenience, the precharge command PREc is a command for performing a write operation to memory cells MCc and precharging the write bit lines WBL(m) and WBL(n) and is issued for an address c stored in the memory.

When the precharge command PREc is issued, the control signal LTO and a write word line WWLc are activated to a high-level voltage at t2. Accordingly, the latch circuits LAT(m) and LAT(n) are connected to the write global bit lines WGBL(m) and WGBL(n) and transmit retained data Cm and Cn thereto, respectively. Therefore, the data Cm from the latch circuit LAT(m) is written to the memory cell MCc(m). The data Cn from the latch circuit LAT(n) is written to the memory cell MCc(n). At this time, the writing transistor WTbl(m) corresponding to the memory cell MCc(m) is in the on-state and the writing transistor WTbl(n) corresponding to the memory cell MCc(n) is in the on-state.

When the write word line WWLc is deactivated to a low-level voltage at t4_1, the memory cells MCc(m) and MCc(n) are electrically separated from the write global bit lines WGBL(m) and WGBL(n) in a state where the data Cm and Cn are stored therein, respectively.

When the control signal LTO is deactivated to a low-level voltage at t8, the latch circuits LAT(m) and LAT(n) are electrically separated from the write global bit lines WGBL(m) and WGBL(n). Therefore, each of the latch circuits LAT(m) and LAT(n) can retain data of another memory cell MCa or MCb in the same column or can retain data to be written from outside.

Meanwhile, due to the issuance of the active command ACTa, the data Am and An of the memory cells MCa(m) and MCa(n) is detected by the sense amplifiers SA(m) and SA(n) via the read global bit lines RGBL(m) and RGBL(n) at t2 to t8.

When the control signal LTI is activated at t9, the latch circuits LAT(m) and LAT(n) are connected to the read global bit lines RGBL(m) and RGBL(n) to load the data Am and An.

The read operation, the write operation, and the refresh operation after t9 may be the same as those after t9 in the first embodiment. Therefore, the second embodiment can achieve effects identical to those of the first embodiment.

In the second embodiment, in a detection period (t0 to t9) from when the data Am and An of the memory cells MCa(m) and Mca(n) is detected by the sense amplifiers SA and until the data Am and An is retained by the latch circuits LAT(m) and LAT(n), the latch circuits LAT(m) and LAT(n) retain the data Cm and Cn of the memory cells MCc(m) and MCc(n). The latch circuits LAT(m) and LAT(n) write back the data Cm and Cn to the memory cells MCc(m) and MCc(n) in this detection period.

Alternatively, in the detection period, the latch circuits LAT(m) and LAT(n) retain data to be written to the memory cells MCc(m) and MCc(n). The latch circuits LAT(m) and LAT(n) write the data to be written to the memory cells MCc(m) and MCc(n) in this detection period.

As described above, in the second embodiment, the detection period (t0 to t9) for data from the memory cells MCa(m) and MCa(n) and the write-back period (or the write period) (t2 to t8) for data to other memory cells MCc(m) and MCc(n) in the same column as those of the memory cells MCa(m) and MCa(n) can be overlapped each other. Accordingly, the second embodiment can further increase the speed of the read operation and the write operation.

### Third embodiment

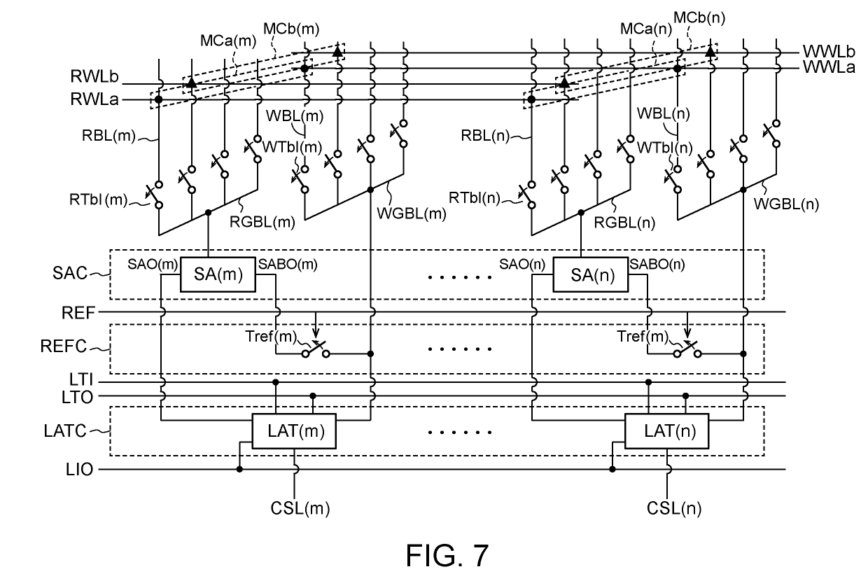

FIG. 7 is a diagram illustrating a configuration example of a gain cell memory according to a third embodiment. In the third embodiment, each of the transistors Tref is connected between an output part SABO for an inverted signal of a sense amplifier SA and a write global bit line WGBL. Each of the transistors Tref is directly connected to the write global bit line WGBL. Associated therewith, the inverters INref in FIG. 3 are omitted. Other configurations of the third embodiment may be identical to those of the first embodiment.

Each of the transistors Tref is connected to the output part SABO for an inverted signal of the sense amplifier SA. Therefore, an inverted signal of read data is transmitted to the write global bit line WGBL. Accordingly, the third embodiment can achieve effects identical to those of the first embodiment while the inverters INref are made unnecessary. The third embodiment may be combined with the second embodiment.

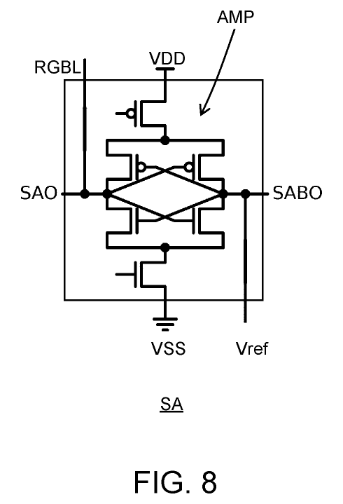

FIG. 8 is a circuit diagram illustrating a configuration example of a sense amplifier. A differential amplifier circuit AMP is provided between an output part SAO for a non-inverted signal and the output part SABO for an inverted signal. The differential amplifier circuit AMP compares a reference voltage Vref with read data from the read global bit line RGBL and amplifies a difference therebetween to output the amplified difference from the output parts SAO and SAOB.

For example, when the voltage of read data is higher than the reference voltage Vref, a high-level voltage is output as a non-inverted signal from the output part SAO and a low-level voltage is output as an inverted signal from the output part SABO. When the voltage of read data is lower than the reference voltage Vref, a low-level voltage is output as a non-inverted signal from the output part SAO and a high-level voltage is output as an inverted signal from the output part SABO.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A semiconductor storage device comprising:
a plurality of first data lines and a plurality of first control lines to be used for writing of data;
a plurality of second data lines and a plurality of second control lines to be used for reading of data;
a plurality of memory cells respectively comprising a first transistor having a gate connected to any of the first control lines and one end connected to any of the first data lines, a second transistor having a gate connected to any of the second control lines and one end connected to any of the second data lines, and a third transistor having a gate connected to another end of the first transistor to retain data from the first data line and having one end connected to another end of the second transistor to be brought to a conduction state according to the data;
a third data line arranged corresponding to the first data lines;
a fourth data line arranged corresponding to the second data lines;
a detection circuit arranged corresponding to the third or fourth data line, having an input part connected to the fourth data line, and configured to detect the data;
a retention circuit corresponding to the third or fourth data line, located between an output part of the detection circuit and the third data line, and configured to retain the data detected by the detection circuit; and
a fourth transistor arranged corresponding to the third or fourth data line and located between the output part of the detection circuit and the third data line.

2. The device of claim 1, further comprising
an inverter circuit arranged in series with the fourth transistor between the output part of the detection circuit and the third data line, wherein
the detection circuit comprises a first output part configured to output data from the fourth data line in a non-inverted state, and a second output part configured to output the data from the fourth data line in an inverted state, and
the fourth transistor is connected to the first output part of the detection circuit.

3. The device of claim 1, wherein
the detection circuit comprises a first output part configured to output data from the fourth data line in a non-inverted state, and a second output part configured to output the data from the fourth data line in an inverted state, and
the fourth transistor is connected between the second output part of the detection circuit and the third data line.

4. The device of claim 3, wherein the fourth transistor is connected directly to the third data line.

5. The device of claim 2, wherein the retention circuit is connected between the first output part of the detection circuit and the third data line.

6. The device of claim 3, wherein the retention circuit is connected between the first output part of the detection circuit and the third data line.

7. The device of claim 4, wherein the retention circuit is connected between the first output part of the detection circuit and the third data line.

8. The device of claim 1, wherein the fourth transistor is brought to a conduction state in a refresh operation of reading data of the memory cells and writing back the data to the same memory cells.

9. The device of claim 1, wherein the fourth transistor is in a non-conduction state in a period in which the retention circuit is electrically connected to the detection circuit or the third data line.

10. The device of claim 1, wherein
the retention circuit comprises
two inverters respectively having one input connected to an output of the other inverter between a first node and a second node,
a fifth transistor arranged between the first node and the detection circuit,
a sixth transistor arranged between the first node and an input/output signal line for inputting and outputting data from and to outside, and
a seventh transistor arranged between the second node and the third data line.

11. The device of claim 10, wherein
in the retention circuit,
the fifth transistor is brought to a conduction state when data is to be loaded from the detection circuit,
the sixth transistor is brought to a conduction state when retained data is to be transmitted to the input/output signal line or when data from the input/output signal line is to be loaded, and
the seventh transistor is brought to a conduction state when retained data is to be transmitted to the third data line.

12. The device of claim 10, wherein the fourth transistor is in non-conduction state when the fifth or seventh transistor is in a conduction state.

13. The device of claim 10, wherein a gate of the sixth transistor is connected to a selection signal line selectively connecting one of a plurality of the retention circuits to the input/output signal line.

14. The device of claim 1, wherein in a period after data of a first memory cell as a data reading target among the memory cells is retained by the retention circuit and before the data retained by the retention circuit is written back to the first memory cell, the detection circuit detects data of a second memory cell as a target for a refresh operation among the memory cells, and the fourth transistor is brought to a conduction state to transmit the data detected by the detection circuit to the third data line and write back the data to the second memory cell.

15. The device of claim 14, wherein the fourth transistor transmits the data detected by the detection circuit to the third data line without transmitting via the retention circuit.

16. The device of claim 1, wherein in a period after data of a first memory cell as a data writing target among the memory cells is retained by the retention circuit and before data updated by the retention circuit is written to the first memory cell, the detection circuit detects data of a second memory cell as a target for a refresh operation among the memory cells, and the fourth transistor is brought to a conduction state to transmit the data detected by the detection circuit to the third data line and write back the data to the second memory cell.

17. The device of claim 16, wherein the fourth transistor transmits the data detected by the detection circuit to the third data line without transmitting via the retention circuit.

18. The device of claim 1, wherein in a period after data of a first memory cell as a data reading target among the memory cells is detected by the detection circuit and before the data is retained by the retention circuit, the retention circuit retains data of a second memory cell different from the first memory cell among the memory cells and writes back the data to the second memory cell.

19. The device of claim 1, wherein in a period after data of a first memory cell as a data reading target among the memory cells is detected by the detection circuit and before the data is retained by the retention circuit, the retention circuit retains data to be written to a second memory cell different from the first memory cell among the memory cells and writes the data to be written to the second memory cell.

20. The device of claim 1, further comprising:
a plurality of eighth transistors arranged between the first data lines and the third data line, respectively; and
a plurality of ninth transistors arranged between the second data lines and the fourth data line, respectively, wherein
the eighth transistors connect any one of the first data lines to the third data line, and
the ninth transistors connect any one of the second data lines to the fourth data line.
